(19) United States
(12) Patent Application Publication
(10) Pub. No.: US 2026/0266449 A1
(43) Pub. Date: Sep. 10, 2026

(54) LIGHT SOURCE ALIGNMENT

(71) Applicant: Ronin Surgical Corp., Austin, TX (US)

(72) Inventors: Clifton Learn, Austin, TX (US); Jeff Ross Gray, San Diego, CA (US)

(73) Assignee: Ronin Surgical Corp., Austin, TX (US)

(21) Appl. No.: 19/461,612

(22) Filed: Jan. 27, 2026

Related U.S. Application Data
(60) Provisional application No. 63/750,726, filed on Jan. 28, 2025.
(60) Provisional application No. 63/780,123, filed on Mar. 28, 2025.

(51) Int. Cl. F21V 19/00; F21V 17/06

(52) U.S. Cl. CPC F21V 19/003; F21V 17/06

(57) ABSTRACT

A high-power lighting system is disclosed. The lighting system includes a light emitting device (LED) having an emitting center and an optical assembly (OA) having an optical axis and a receptacle configured to accept the LED, wherein the emitting center is located within a predetermined perpendicular distance of the optical axis when the LED is accepted into the receptacle.

### CROSS REFERENCE TO RELATED APPLICATIONS

This application claims priority to, and the benefit of, U.S. Provisional Application No. 63/750,726, entitled “LIGHT SOURCE ALIGNMENT” and filed Jan. 28, 2025, and to U.S. Provisional Application No. 63/780,123, entitled “LIGHT SOURCE ALIGNMENT” and filed Mar. 28, 2025, the disclosures of which are herein incorporated by this reference in their entirety.

### BACKGROUND

### Field

The present invention generally relates to construction of an optical system that comprises a light source.

### Description of the Related Art

Optical systems are sensitive to the position and orientation of optical elements with respect to each other and to the optical axis of the system. Laser interferometry, autocollimation, and beam profiling are widely used for precisely aligning mirrors and lenses, although use of these methods of alignment inherently requires adjustable mounts for the components and complicates the manufacturing process by adding an alignment adjustment step.

There is an increasing focus on increasing the efficiency of lighting systems, for example flashlights, that is commonly achieved by using light-emitting diodes (LEDs) in place of incandescent, halogen, and other conventional sources. LEDs are commonly provided as a surface-mount integrated-circuit (IC) device soldered to a printed circuit board (PCB). The PCB is located in a plane perpendicular to the optical axis by alignment pins which engage holes in the substrate of the PCB. The positioning accuracy of the LED relative to the other optical elements in this construction is limited by the material properties of the substrate and the lateral positioning accuracy of the LED relative to the PCB. The substrate is conventionally a fiberglass-reinforced epoxy laminate which is relatively soft. The heat generated by a LED further affects the lateral position of the LED as the conventional substrate has a relatively high coefficient of thermal expansion.

Therefore, in view of the above, there is a need for an improved lighting system that addresses these deficiencies.

### SUMMARY

A lighting system is disclosed that is capable of precisely positioning a light-emitting diode within the lighting system that is simple to assemble, avoids a need for measurement and adjustment, and maximizes the transfer of heat from the light source to a heat sink, e.g., to minimize the thermally induced changes in position. The invention described herein fulfills this need.

In an aspect, the present disclosure provides for a lighting system comprising a light emitting device (LED) and an optical assembly (OA). The LED may comprise an emitting center. The OA may comprise an optical axis and a receptacle. The receptacle may be configured to accept the LED. The LED may be accepted into the receptacle. The emitting center may be disposed within a predetermined perpendicular distance of the optical axis.

In another aspect, the present disclosure provides a light-emitting assembly comprising a printed circuit board (PCB) and a light emitting device (LED). The PCB may comprise a first body, a cooling surface, a transfer surface, an electrical insulator, and an electrically conductive trace. The first body may be composed of a thermally conductive material and may have a top side and a bottom side. The cooling surface may form a portion of the top side. The transfer surface may form a portion of the bottom side and may be separated from the cooling surface by at least 0.2 millimeters. The electrical insulator may be fixed attached to the top side of the first body. The electrically conductive trace may be fixed attached to the electrical insulator and may be electrically isolated from the first body. The LED may comprise a second body, an electrical contact surface, and a heat conductive surface. The electrical contact surface may be fixedly attached to the second body and may be soldered to the electrically conductive trace of the PCB. The heat conductive surface may be fixedly attached to the second body and may be in thermally conductive contact with the cooling surface of the PCB.

### BRIEF DESCRIPTION OF THE DRAWINGS

Aspects of the disclosure are herein described, by way of example only, with reference to the accompanying drawings. With specific reference now to the drawings in detail, it is stressed that the particulars shown are by way of example and are for purposes of illustrative discussion of aspects of the disclosure. The description and the drawings, considered alone and together, make apparent to those skilled in the art how aspects of the disclosure may be practiced.

FIG. 1 depicts a schematic of a simplified optical system.

FIGS. 2A-2B depict an exemplary attachment of a light-emitting device (LED) to a printed circuit board (PCB).

FIG. 3 is a perspective view of an exemplary lighting system, in accordance with the present disclosure.

FIG. 4 is an exploded view of certain internal components of an exemplary lighting system, in accordance with the present disclosure.

FIG. 5 is a perspective view of a portion of the exploded view of FIG. 4, in accordance with the present disclosure.

FIG. 6 is a perspective view of the components of FIG. 4, in accordance with the present disclosure.

FIG. 7 is a cross-section of an exploded view of an exemplary lighting system, in accordance with the present disclosure.

### DETAILED DESCRIPTION

This description is intended to illustrate some particular embodiments of the disclosure and not to exhaustively specify all permutations, combinations and variations thereof. Features illustrated with respect to one embodiment may be incorporated into another embodiment, and features illustrated with respect to a particular embodiment may be deleted from that embodiment. In addition, numerous variations and additions to the various embodiments suggested herein will be apparent to those skilled in the art in light of the instant disclosure and do not depart from the instant disclosure. In some instances, well-known structures, interfaces, and processes have not been shown in detail in order not to unnecessarily obscure the invention. It is intended that no part of this specification be construed to effect a disavowal of any part of the full scope of the invention.

### Problem

Modern lighting systems often use an LED as the light source. As the light is emitted from an LED from a very small area, it is desirable to align the center of the light-emitting area with the optical axis of the system. Conventional systems have a first lateral tolerance between the LED and the PCB to which it is attached and at least one second lateral tolerance between the PCB and the optical axis. The first lateral alignment is achieved by soldering, which is not capable of achieving precision alignment.

### Solution

The solutions disclosed herein overcome the deficiencies of conventional design by (1) utilizing aspects of the LED itself to interact directly with aspects of the optical assembly so as to reduce the number of terms in the tolerance chain between the LED and the optical axis, and (2) replacing the standard fiberglass-reinforced epoxy laminate of the PCB with a thermally conductive metal such as, for example, copper. The combination of the increased cross-sectional area of the thermally conductive path and the increase in the end-to-end thermal conductivity enhances the transfer of heat from the LED to the heat sink, which maintains the LED at a lower operating temperature thereby enhancing the performance and/or operating life of the LED and reducing thermally induced misalignment between the LED and the optical axis.

Unless otherwise defined herein, all technical and scientific terms used herein have the same meaning as commonly understood by one of ordinary skill in the art to which this disclosure belongs. The terminology used in the description of the disclosure herein is for the purpose of describing particular aspects or embodiments only and is not intended to be limiting of the disclosure. References to techniques employed herein are intended to refer to the techniques as commonly understood in the art, including variations on those techniques or substitutions of equivalent techniques that would be apparent to one of skill in the art.

### Terminology

As used within this disclosure, the term “light” means electromagnetic energy having a wavelength within the range, or band, of approximately 10 nm to approximately 1 mm, wherein “ultraviolet” (UV) light is generally associated with the range of approximately 10-400 nm, also referred to as the UV band, “visible” light is generally associated with the range of approximately 400-750 nm, also referred to as the visible band, and “infrared” (IR) light is generally associated with the range of approximately 750 nm-1 mm, also referred to as the IR band.

As used within this disclosure, the phrase “light emitting diode” and the associated acronym “LED” refer to any of a semiconductor die that emits light when electric power is provided, a semiconductor device that includes the semiconductor die and one or more of a case, a lens, electrical leads, and heat-conducting elements, and an integrated circuit (IC) package that includes the semiconductor device as well as one of more of a control circuit, a memory, a package, a signal input, a signal output, a power input.

As used within this disclosure, the term “spring” refers to any component that applies a force or torque to another object so as to urge the object in a predetermined direction, including but not limited to deformable rigid elements, compressible materials, and active devices such as a magnet and a solenoid.

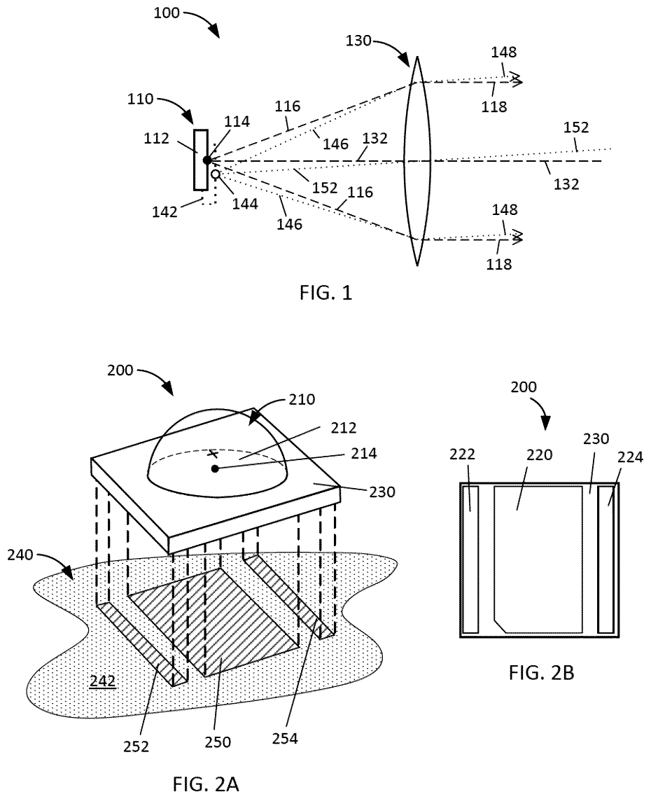

FIG. 1 depicts a schematic of a simplified optical system 100. In this example, the system 100 comprises an LED 110 and an optical assembly (OA) 130, depicted here as a single lens, with an optical axis 132. The LED 110 has a body 112 shown in a nominal location with its emitting center 114 co-located with the ideal focus point of the OA 130 that lies on the optical axis 132. When light is emitted, in an ideal model of the LED 110, from the emitting center 114, example rays 116 propagate toward the OA 130 and are refracted into parallel ideal rays 118.

If the body of LED 110 is displaced to position 142, the emitting center moves to location 144. Light emitted from emitting center 114 at location 144 forms rays 146 that are refracted by OA 130 into parallel rays 148 that propagate at an angle from the parallel ideal rays 118. This is modeled as a shift of the optical axis 132 to an angled optical axis 152 that will not provide the desired optical behavior for OA 130.

FIG. 2A depicts an exemplary attachment of an LED 200 to a PCB 240. The LED 200 comprises an LED body 230 to which is attached a light-emitting module 210. Light emitting module 210 has a light-emitting area 212, with an emitting center 214 that is located at the center of the light-emitting area 212. The emitting center 214 serves as the ideal origin of light emitted by the LED 200 for optical modeling purposes.

FIG. 2B depicts exemplary features on the underside of the LED body 230, which are not visible in FIG. 2A. In this example, the LED 200 has a cathode 222 and an anode 224 formed as electrically conductive contacts on the LED body 230. The center pad 220 is thermally coupled to the heat-generation elements within the LED 200 and electrically isolated from cathode 222 and anode 224.

Returning to FIG. 2A, the PCB 240 has a PCB body 242 with a top side on which a thermally conductive area 250 and electrically conductive areas 252, 254 are located. In certain embodiments, the center pad 220, the cathode 222, and the anode 224 of the LED 200 are respectively soldered to thermally conductive area 250 and electrically conductive areas 252, 254 of the PCB 240 when the LED 200 is attached to the PCB 240. In certain embodiments, electrically conductive areas 252, 254 are electrically connected to cathode 222 and anode 224 by electrically conductive adhesive, jumper wires, or any other suitable means of providing an electrical connection. In certain embodiments, center pad 220 is thermally connected to thermally conductive area 250 by a thermally conductive adhesive, a thermally conductive paste, or any other suitable means of providing a thermal connection.

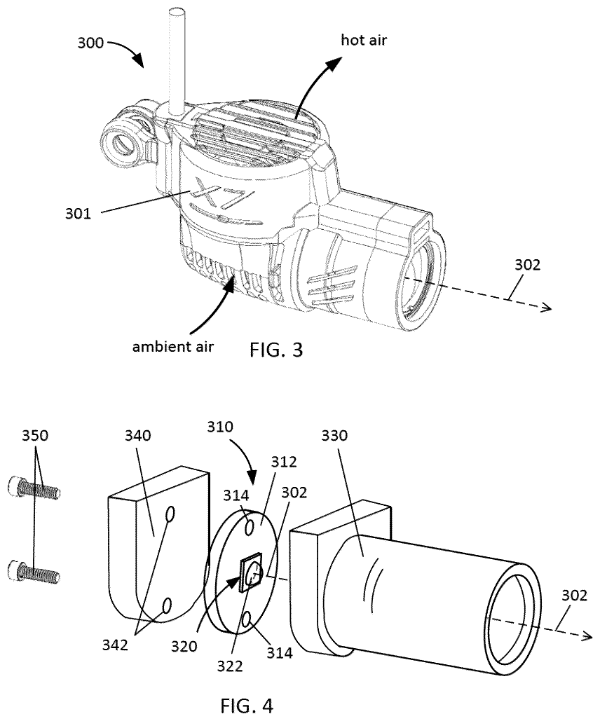

FIG. 3 is a perspective view of an exemplary lighting system 300, in accordance with the present disclosure. The lighting system 300 comprises a housing 301 having an air intake and an air exit through which air flows to cool the internal components. The lighting system 300 has an optical axis 302 along which a beam of light (not shown in FIG. 3) is projected when the lighting system 300 is in operation.

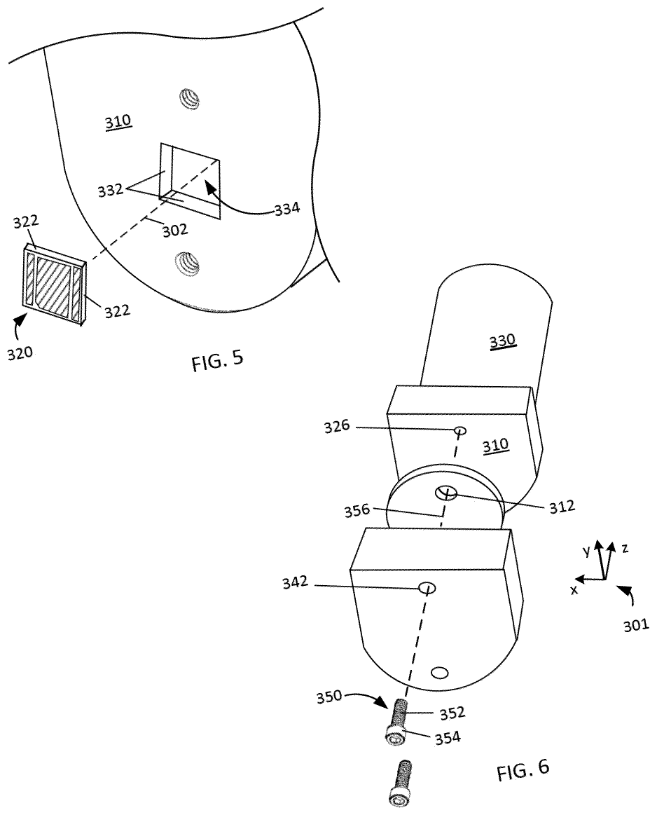

FIG. 4 is an exploded view of certain internal components of an exemplary lighting system, such as lighting system 300 of FIG. 3, in accordance with the present disclosure. In an example embodiment, lighting system 300 comprises: the optical assembly (OA) 330 that comprises the optical axis 302; a LED/PCB assembly 310 that includes an LED 320 mounted on a PCB 312; and a heat sink 340. In certain embodiments, the optical axis 302 intersects the light-emitting region 322 at an emitting center (not illustrated in FIG. 4). In certain embodiments, the optical axis 302 is the ideal axis for the light emitted by the LED 320 to properly propagate through the OA 330 and emerge in the proper direction with the proper characteristics. In certain embodiments, the optical axis 302 is refracted, reflected, or otherwise folded within the OA 330.

These components may be held together, when assembled, by fasteners 350, e.g., threaded screws. Fasteners 350 may comprise screws, pins, bolts, or may be any suitable device or mechanism for fastening the various components described herein to one another. Fasteners 350 may pass through holes 342 in the heat sink 340, through oversize holes 314 in the PCB 312, and may engage retention features (not illustrated in FIG. 4), e.g., threaded holes, in the OA 330. In certain embodiments, a fastener 350 comprises a head and a shaft comprising an engagement feature, e.g., threads on the shaft, compatible with the retention features of the OA 330. In certain embodiments, fastener 350 is configured to be installed such that the head applies a force to the back surface of the PCB, e.g., via a force applied to the heatsink 340, that urges the PCB 312 toward the OA 330 when the fastener 350 is actuated, e.g., rotated. In certain embodiments, the heat sink 340 is in thermal contact with the PCB 312 when the fastener 350 is fully actuated, e.g., torqued to a predetermined level.

In certain embodiments, the fasteners 350 may be a quarter-turn retention pin and the retention features of the OA 330 may be compatible with retention pins. In certain embodiments, the fasteners 350 may be pins with one-time engagement features. e.g., a barbed tip, or other selected fastener configured to attach components together, and the retention features of the OA 330 may be selected to be compatible with the selected fastener.

FIG. 5 is a perspective view of a portion of the exploded view of FIG. 4, as seen from a different direction, in accordance with the present disclosure. The LED 320 is seen from its underside and sides 329 are visible. In this example, the LED 320 has a rectangular profile and there are two additional sides 329 that are not visible in FIG. 5. In certain embodiments, one of the visible sides 329 forms a first reference feature while a second side 329 that is on an opposite side of LED 320 (and not visible in FIG. 5) forms a second reference feature. In certain embodiments, the first and second reference features are separated by a width. In certain embodiments, the remaining pair of sides 329 form third and fourth reference surfaces that are arranged perpendicular to the first and second reference surfaces.

A receptacle 334 comprising side surfaces 332 is visible in the body of OA 330. In this example, the receptacle 334 has a rectangular profile and there are two additional side surfaces 332 that are not visible in FIG. 5. In certain embodiments, two side surfaces 332 of the receptacle 334 form a datum feature and a positioning feature that is opposite of the datum feature. In certain embodiments, there is a gap between the datum feature and a positioning feature. In certain embodiments, a second datum feature and a second positioning feature opposite of the second datum feature are formed by the remaining side surfaces 332 and orthogonal to the first datum and positioning features. In certain embodiments, a positioning feature comprises a spring element (not visible in FIG. 5) configured to urge a component disposed between a datum feature and the positioning feature toward the datum feature.

In certain precision designs, it is desirable that the emitting center of the LED 320 be within a predetermined distance of the optical axis 302. In certain embodiments, the gap between the datum feature and a positioning feature of the receptacle 334 is larger than the width between the first and second reference features of the LED 320. In certain embodiments, the difference between the gap and the width is a first clearance. In certain embodiments, the first clearance distance is less than the predetermined distance such that acceptance of the LED 320 into the receptacle 334 ensures that the LED 320 is properly aligned with the OA 330. In certain embodiments, the first clearance is selected from about 1 mm, about 0.5 mm, about 0.2 mm, and about 0.1 mm. In certain embodiments, the first clearance is between about 1 mm and about 0.1 mm, more preferably between about 0.5 mm and 0.1 mm, and more preferably between about 0.2 mm and 0.1 mm. In certain embodiments, the tolerances for the width and the gap of the LED 320 and the OA 330, respectively, are selected to add up to the value of the first clearance, e.g., each tolerance is set to half of the first clearance. In various embodiments, each tolerance may be set to an individual portion of the first clearance, each individual portion summing to about the first clearance.

In certain embodiments, the PCB 312 (FIG. 4)and the OA 330 are configured such that the LED/PCB assembly 310 (FIG. 4) is able to move laterally, i.e., perpendicular to the optical axis 302, over a distance greater than the first clearance. Stated another way, oversize holes 314 may be sized such that variation in the alignment of the PCB 312 to the OA 330 may be greater than the first clearance. In this manner, the first clearance is the controlling aspect of alignment of the assembly of the LED/PCB assembly 310 with the OA 330. In this manner, allowance is made for lateral movement of the LED/PCB assembly 310 and for less robust tolerances in PCB 312 construction and attachment of LED 320 to PCB 312 without impacting the alignment of LED 320 with the OA 330.

FIG. 6 is a perspective view of the components of FIG. 4, in accordance with an exemplary embodiment. In this view of this example embodiment, it can be seen how the shaft 352 of fastener 350 passes along line 356 through hole 342 in the heat sink 340 (FIG. 4) and through oversize hole 314 of the LED/PCB assembly 310 to engage retention feature 326 of the OA 330. In certain embodiments, the diameter of the head 354 is greater than the diameter of hole 342 and therefore head 354 bears against the heat sink 340. In certain embodiments, an additional component, e.g., a washer (not shown in FIG. 6), is provided such that head 354 bears against the washer which then bears against the heat sink 340. In certain embodiments, the fastener 350 is configured such that a portion of the fastener 350 bears against the heat sink 340 while a portion of the fastener 350 extends to and engages the OA 330 so as to bring the heat sink 340 and the OA 330 toward each other when the fastener 350 is activated.

As the fastener 350 shown in FIG. 6 is actuated, e.g., rotated while engaged in the retention feature 326, the heat sink 340 is drawn toward the OA 330 along the z-axis of coordinate system 331, thereby bringing a face of the heat sink 340 into contact with the PCB 312 and bringing the LED/PCB assembly 310 into contact with the OA 330. In certain embodiments, the PCB 312 comes into contact with the OA 330 and prevents further relative motion of the LED/PCB assembly 310 toward the OA 330 before the LED 320 comes into contact with a surface of OA 330 which prevents further motion in the z-axis. In this example, the PCB 312 establishes the relative position of the LED/PCB assembly 310 and the OA 330 along the z-axis and the LED 320 establishes the relative position of the LED/PCB assembly 310 and the OA 330 in the x-axis and y-axis. In certain embodiments, the difference between the diameter of oversize hole 314 and the shaft 352 is a second clearance that is larger than the first clearance. When the second clearance is greater than the first clearance, the shaft of fastener 350 does not contact the side of oversize hole 314 and the first clearance controls the x-y position of the LED 320 with respect to the optical axis 302 (FIG. 5) of OA 330. Stated another way, the LED/PCB assembly 310 may have a greater range of lateral movement about shaft 352 than LED 320 does within OA 330. In this manner, the positioning of LED 320 within receptacle 334 of the OA 330 controls the x-y movement of the LED/PCB assembly 310, and deviation in the alignment of the LED 320 to the PCB 312 may be corrected.

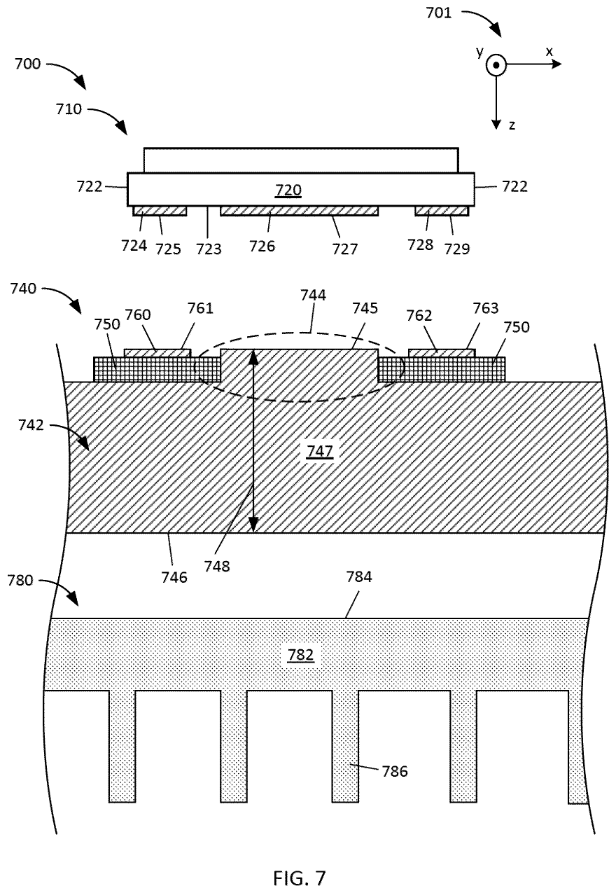

FIG. 7 is a cross-section of an exploded view of an exemplary lighting system 700, in accordance with the present disclosure. The lighting system 700 comprises an LED 710, a PCB 740, and a heat sink 780. The LED has a base 720 with a bottom 723 and at least one side 722. An anode 724 with an anode surface 725, a center pad 726 with a center pad surface 727, and a cathode 728 with a cathode surface 729 are all attached to the bottom 723. In certain embodiments, the anode surface 725, center pad surface 727, and cathode surface 729 are approximately co-planar.

In certain embodiments, there is no alignment feature controlling relative position of the LED 710 and the PCB 740 in the x-y plane of coordinate system 701. In certain embodiments, one or more of anode surface 725, center pad surface 727, and cathode surface 729 are soldered respectively to anode trace surface 761, thermal contact surface 745, and cathode trace surface 763. In certain embodiments, center pad surface 727 is thermally coupled to thermal contact surface 745, for example with a thermally conductive paste disposed between center pad surface 727 and thermal contact surface 745. In certain embodiments, the relative x-y position and/or orientation of the LED 710 and the PCB 740 is controlled by the respective soldering of anode surface 725, center pad surface 727, and cathode surface 729 to the anode trace surface 761, thermal contact surface 745, and cathode trace surface 763. In certain embodiments, the soldering process achieves a positioning tolerance that is less than the difference between the second clearance and the first clearance. In certain embodiments, the positioning tolerance of the soldering process is further reduced to account for tolerances in the relative position of the side surfaces 332 (FIG. 5) and retention feature 326 (FIG. 6) in the OA 330.

In certain embodiments, the PCB 740 comprises a substrate 742, one or more insulators 750, an anode circuit trace 760 having an anode trace surface 761, and a cathode circuit trace 762 with a cathode trace surface 763. In certain embodiments, the substrate 742 comprises a main body 747 and an extension 744 having a thermal contact surface 745.

In certain embodiments, the substrate 742 is a single material throughout, excluding surface coatings such as solder mask and markings. In certain embodiments, the substrate 742 may be a composite material, and/or may comprise multiple materials layered or suitably arranged. In certain embodiments, the single material of the substrate 742 extends from thermal contact surface 745 to surface 746 over an area equal to or greater than the x-y area of surface 745. In certain embodiments, the single material of the substrate 742 extends from thermal contact surface 745 and from under insulator 750 to surface 746 over an area equal to or greater than the x-y area of the base 720 of the LED 710. In certain embodiments, the material of substrate 742 has a thermal conductivity greater than 50 W/m·K. In certain embodiments, the material of the substrate 742 has a thermal conductivity greater than 200 W/m·K. In certain embodiments, the material of the substrate 742 is a metal. In certain embodiments, the material of the substrate 742 consists of one of more of a group comprising silver, copper, gold, aluminum, and tungsten. In certain embodiments, the extension 744 is integral with the main body 747 of substrate 742. In certain embodiments, the extension 744 is formed by machining away a portion of main body 747 occupying the intended location of the insulator 750. In certain embodiments, the extension 744 is formed by adding material, e.g., plating, onto the main body 747 of substrate 742. In certain embodiments, there is a thermally conductive boundary between the extension 744 and the main body 747. In certain embodiments, the thermal contact surface 745 is co-planar with one or more of anode trace surface 761 and cathode trace surface 763.

In certain embodiments, center pad surface 727 of the LED 710 is in thermally conductive contact with thermal contact surface 745 of the PCB 740 and surface 746 of the PCB 740 is in thermally conductive contact with surface 784 of the heat sink 780 when the lighting system 700 is assembled, thereby providing an improved thermal connection between the heat-generating light source of LED 710 and the heat sink 780.

The performance of a high-intensity lamp that provides a narrow beam of light, for example a surgical headlamp, is improved by achieving precision alignment of the light source and the optics and improved heat dissipation to maintain a high-power light source at an acceptable temperature. The disclosed embodiments provide an increase in optical efficiency, improve the lifetime of the lighting system, reduces the product size, e.g., battery size and smaller heat sinks, reduces temperature-induced degradation, e.g., color shift, and provides more uniform illumination. The former is achieved by utilizing features of the LED itself to interact with positioning features of the optical assembly, thereby bypassing the additional positional errors induced by relying on the PCB to locate the LED relative to the optical assembly, and replacing the conventional PCB material, which has a low thermal conductivity, with a material, such as copper, that has a high thermal conductivity. The use of a material with a high thermal conductivity for the PCB provides improved cooling of the LED, compared to conventional designs, e.g., small-diameter copper vias in a fiberglass-reinforced epoxy laminate.

Unless the context indicates otherwise, it is specifically intended that the various features of the disclosure described herein can be used in any combination. Moreover, the present disclosure also contemplates that in some embodiments of the disclosure, any feature or combination of features set forth herein can be excluded or omitted.

The methods disclosed herein comprise one or more steps or actions for achieving the described method. The method steps and/or actions may be interchanged with one another without departing from the scope of the present disclosure. In other words, unless a specific order of steps or actions is required for proper operation of the embodiment, the order and/or use of specific steps and/or actions may be modified without departing from the scope of the present disclosure.

As used in the description of the disclosure and the appended claims, the singular forms “a,” “an” and “the” and the like are intended to include to be interpreted as equivalent to the phrase “at least one” and comprise the plural forms as well, unless the context clearly indicates otherwise. Reference to an element in the singular is not intended to mean “one and only one” unless specifically so stated.

As used in the description of the disclosure and the appended claims, pronouns in the masculine (e.g., his) include the feminine and neuter gender (e.g., her and its) equivalent and vice versa.

As used herein, “and/or” refers to and encompasses any and all possible combinations of one or more of the associated listed items as well as singular usage of each item.

As used in the description of the disclosure and the appended claims, terms such as “top,” “bottom,” “upper,” “lower,” “left,” “right,” “front,” “rear,” and the like should be understood as referring to an arbitrary frame of reference. Thus, a top surface may extend upwardly, downwardly, diagonally, or horizontally in a particular embodiment without limiting the orientation in other embodiments.

As used herein, the terms “aspect” and “embodiment” are used to identify examples as to how the disclosure may be utilized and do not necessarily identify features or components that essential to the subject technology or that apply to all configurations of the subject disclosure. A disclosure relating to an aspect may apply to all configurations, or one or more configurations.

As used herein, the term “exemplary” means “serving as an example or illustration.” Any aspect or design described herein as “exemplary” is not necessarily to be construed as preferred or advantageous over other aspects or designs.

As used herein, the terms “substantially,” “approximately,” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” aligned can refer to a range of angular variation of less than or equal to ±10°, such as less than or equal to ±5°, less than or equal to ±4°, less than or equal to ±3°, less than or equal to ±2°, less than or equal to ±°, less than or equal to ±0.5°, less than or equal to ±0.1°, or less than or equal to ±0.05°.

As used herein, the terms “include,” “contain,” “has,” “have,” and the like are intended to be inclusive in a manner similar to the term “comprise” as interpreted when employed as a transitional word in a claim.

As used herein, phrases such as “between X and Y” and “between about X and Y” should be interpreted to include X and Y. As used herein, phrases such as “between about X and Y” mean “between about X and about Y” and phrases such as “from about X to Y” mean “from about X to about Y.”

Although the relationships among various components are described herein and/or are illustrated as being orthogonal or perpendicular, those components can be arranged in other configurations in some embodiments. For example, the angles formed between the referenced components can be greater or less than 90 degrees in some embodiments.

Although various components are illustrated as being flat and/or straight, those components can have other embodiments such as curved or tapered.

Headings and subheadings, if any, are used for convenience only and do not limit the invention.

All structural and functional equivalents to the elements of the various aspects described throughout this disclosure are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

This application includes description that is provided to enable a person of ordinary skill in the art to practice the various aspects described herein. While the foregoing has described what are considered to be the best mode and/or other examples, it is understood that various modifications to these aspects will be readily apparent to those skilled in the art, and the generic principles defined herein may be applied to other aspects. Although embodiments of the present disclosure have been described and illustrated in detail, it is to be clearly understood that the same is by way of illustration and example only and is not to be taken by way of limitation, the scope of the present invention being limited only by the terms of the appended claims.

We claim:

1. A lighting system, comprising:
a light emitting device (LED) comprising an emitting center; and
an optical assembly (OA) comprising an optical axis and a receptacle configured to accept the LED;
wherein:
the LED is accepted into the receptacle; and
the emitting center is disposed within a predetermined perpendicular distance of the optical axis.

2. The lighting system of claim 1, wherein:
the receptacle of the OA further comprises a datum feature and a positioning feature separated from the datum feature by a gap;
the LED further comprises a first reference feature and a second reference feature separated from the first reference feature by a width;
the second reference feature is proximate to the positioning feature when the LED is accepted into the receptacle with the first reference feature proximate to the datum feature; and
the gap is greater than the width by a first clearance that is less than or equal to the predetermined perpendicular distance.

3. The lighting system of claim 2, further comprising:
a printed circuit board (PCB) comprising:
a front surface physically attached to the LED; and
a back surface opposite the front surface; and
a fastener comprising a head and a shaft comprising an engagement feature that is engaged with a retention feature of the OA;
wherein:
the fastener is configured such that the head applies a force to the back surface of the PCB when the fastener is actuated, thereby urging the PCB toward the OA; and
the PCB and the OA are configured such that movement of the PCB in a plane perpendicular to the optical axis is constrained, prior to actuation of the fastener, only by respective contact between the first reference feature and the second reference feature of the LED and the datum feature and the positioning feature of the OA.

4. The lighting system of claim 3, wherein:
the receptacle is a first rectangle comprising a first pair of opposite sides formed by the datum feature and the positioning feature; and
the LED is a second rectangle comprising a second pair of opposite sides formed by the first reference feature and the second reference feature.

5. The lighting system of claim 3, wherein:
the fastener is disposed such that the shaft of the fastener passes through a hole that passes through the PCB from the back surface to the front surface;
a first diameter of the hole is greater than a second diameter of the shaft of the fastener by a second clearance that is greater than the first clearance such that the fastener does not contact a side of the hole when the LED is accepted into the receptacle; and
the head of the fastener has a third diameter that is greater than the first diameter of the hole.

6. The lighting system of claim 3, wherein:
the LED is fixedly positioned relative to the OA when the fastener is fully actuated while the LED is accepted into the receptacle.

7. The lighting system of claim 6, wherein:
the predetermined perpendicular distance is between about 1 millimeter and about 0.1 millimeter.

8. A light-emitting assembly, comprising:
a printed circuit board (PCB) comprising:
a first body composed of a thermally conductive material and comprising a top side and a bottom side;
a cooling surface that forms a portion of the top side;
a transfer surface that forms a portion of the bottom side and is separated from the cooling surface by at least 0.2 millimeter;
an electrical insulator fixedly attached to the top side of the first body; and
an electrically conductive trace fixedly attached to the electrical insulator and electrically isolated from the first body; and
a light emitting device (LED) fixedly attached to the PCB, comprising:
a second body;
an electrical contact surface fixedly attached to the second body and soldered to the electrically conductive trace of the PCB; and
a heat conductive surface fixedly attached to the second body and in thermally conductive contact with the cooling surface of the PCB.

9. The light-emitting assembly of claim 8, wherein the transfer surface is separated from the cooling surface by at least 1.6 millimeters.

10. The light-emitting assembly of claim 8, wherein the thermally conductive material consists of one of more of a group consisting of silver, copper, gold, aluminum, and tungsten.

11. The light-emitting assembly of claim 8, wherein:
the heat conductive surface of the LED has a first area;
the cooling surface of the PCB has a second area that is at least 80% of the first area; and
the transfer surface of the PCB has a third area that is at least 5× the second area.

12. The light-emitting assembly of claim 11, wherein the third area is at least 10× the second area.

13. The light-emitting assembly of claim 8, wherein the heat conductive surface and the electrical contact surface of the PCB are coplanar.
